(19) United States
(12) Patent Application Publication
(10) Pub. No.: US 2016/0218026 A1
(43) Pub. Date: Jul. 28, 2016

(54) SEMICONDUCTOR MANUFACTURING APPARATUS, DIAGNOSTIC SYSTEM FOR SEMICONDUCTOR MANUFACTURING APPARATUS, AND METHOD FOR MANUFACTURING SEMICONDUCTOR DEVICE

(71) Applicant: RENESAS ELECTRONICS CORPORATION, Tokyo (JP)

(72) Inventor: Kaichiro KOBAYASHI, Ibaraki (JP)

(21) Appl. No.: 14/973,392

(22) Filed: Dec. 17, 2015

(30) Foreign Application Priority Data
Jan. 22, 2015 (JP) 2015-010240

(51) Int. Cl. H01L 21/67; H01L 21/66

(52) U.S. Cl. CPC H01L 21/67276; H01L 22/10

(57) ABSTRACT

A semiconductor manufacturing apparatus capable of stable operation includes a processing chamber where a wafer is treated, a vacuum pump that is coupled with the processing chamber and evacuates the processing chamber, a monitor that measures the drive state of the vacuum pump, and an exhaust assisting device that is arranged on the exhaust side of the vacuum pump, in which the monitor measures the drive state of the vacuum pump in a state the vacuum pump and the exhaust assisting device are driven.

### CROSS-REFERENCE TO RELATED APPLICATIONS

The disclosure of Japanese Patent Application No. 2015-010240 filed on Jan. 22, 2015 including the specification, drawings and abstract is incorporated herein by reference in its entirety.

### BACKGROUND

The present invention relates to a semiconductor manufacturing apparatus and a method for manufacturing a semiconductor device, and relates specifically to diagnosis of the semiconductor manufacturing apparatus.

The semiconductor device such as a microcomputer, memory, and system LSI (Large Scale Integrated circuit) is manufactured by forming an integrated circuit by repeating various surface treatments on a semiconductor substrate (wafer) such as silicon by plural times.

Out of the various surface treatments, in the CVD (Chemical Vapor Deposition) step of forming a thin film over the semiconductor substrate and the dry etching step of removing the unnecessary film, the wafer is subjected to treatment under vacuum after the processing chamber to which the wafer has been transported is evacuated by a vacuum pump.

The vacuum pump is liable to have breakdowns often unexpectedly, and the wafer under processing becomes scrap at the time of the failure.

Therefore, there is such a trial that a system for monitoring the state of the vacuum pump is arranged in the semiconductor manufacturing apparatus, the electric current value and electric power value of the vacuum pump, the temperature, pressure and the like of the vacuum pump are monitored constantly, variation is detected when the variation occurs, and an alarm is issued in advance as the abnormality of the vacuum pump.

As a related art of the present technical field, there is such technology as Japanese Unexamined Patent Application Publication No. Hei 11(1999)-062846 for example in which there is disclosed “a vacuum pump failure predict system for predicting a clogging failure that occurs by precipitates precipitated inside a casing of a vacuum pump used in an evacuation system of a semiconductor manufacturing apparatus, in which a sensor unit that includes at least an AE sensor detecting the AE (acoustic emission) generated by the vacuum pump and a diagnostic unit that analyzes and diagnoses a signal from the sensor unit are arranged in each vacuum pump, and a display unit that collectively displays the state and the diagnostic result of each vacuum pump is coupled onto a LAN”.

According to the vacuum pump failure predict system described above, it is stated that the product defect caused by an unexpected failure of the pump can be avoided, the yield of the product can be improved, and the maintenance cost of the pump can be reduced by predicting beforehand a clogging failure that occurs by precipitates precipitated inside a casing of a vacuum pump used in an evacuation system of a semiconductor manufacturing apparatus and giving an alarm for exchanging the pump.

### SUMMARY

However, it is difficult to detect the abnormality of the vacuum pump. Normally, the vacuum pump is used in a state a high load is applied, and therefore the electric current value, electric power value or pressure thereof consistently repeats minute fluctuation. Therefore, it is difficult to determine such minute fluctuation a sign of the failure. Also, because the drastic variation is usually seen only several minutes before the failure, even when the variation is detected beforehand and an alert is given, start of manufacturing the product usually cannot be stopped in time.

According to the vacuum pump failure predict system of Japanese Unexamined Patent Application Publication No. Hei 11(1999)-062846 described above, an AE sensor is arranged in the vacuum pump and the failure is predicted by detecting the AE (acoustic emission) generated in the vacuum pump. However, since the detection sensitivity of the sensor varies according to the precipitation state of the precipitates precipitated inside the casing of the vacuum pump, prediction of such unexpected failure of the vacuum pump as described above is difficult.

The object of the present application is to stabilize the operation of a semiconductor manufacturing apparatus that subjects the wafer to a treatment. Further, the object of the present application is to improve the productivity in manufacturing a semiconductor device by utilizing such apparatus. Other problems and new features will be clarified from the description of the present specification and the attached drawings.

According to an embodiment of the present invention, in a semiconductor manufacturing apparatus that subjects a wafer to a treatment, the drive state of a vacuum pump is measured in a state both of the vacuum pump coupled with a processing chamber and an exhaust assisting device arranged on the exhaust side of the vacuum pump are driven.

According to the embodiment of the present invention, stable operation of the semiconductor manufacturing apparatus that subjects a wafer to a treatment becomes possible. Also, the productivity in manufacturing the semiconductor device can be improved.

### BRIEF DESCRIPTION OF THE DRAWINGS

FIG. 1 is a drawing showing a general outline of a representative semiconductor manufacturing apparatus according to a related art.

FIG. 2 is a drawing showing a general outline of a semiconductor manufacturing apparatus related to an embodiment of the present invention.

FIG. 3 is a partial cross-sectional view explaining an outline of a vacuum pump related to an embodiment of the present invention.

FIG. 4 is a drawing showing the relationship between the elapsed time and the vacuum pump electric current value.

FIG. 5 is a drawing showing a general outline of a semiconductor manufacturing apparatus related to an embodiment of the present invention.

FIG. 6 is a drawing showing a general outline of a semiconductor manufacturing apparatus related to an embodiment of the present invention.

FIG. 7 is a flowchart showing an outline of the manufacturing step of the semiconductor device.

FIG. 8 is a flowchart showing an outline of a preprocess of the manufacturing step of the semiconductor device.

### DETAILED DESCRIPTION

Below, the embodiments of the present invention will be explained using the drawings. Also, in each drawing, a same reference sign will be given to a member having a same configuration, and detailed explanation of the duplicated portion will be omitted.

### First Embodiment

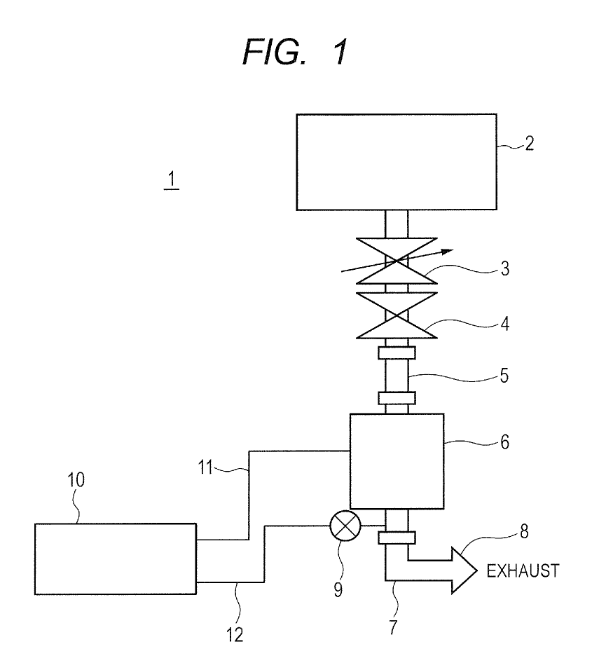

First, a representative semiconductor manufacturing apparatus according to a related art will be explained using FIG. 1. FIG. 1 shows a general outline of a semiconductor manufacturing apparatus such as a CVD device and a dry etching device which treats the wafer under vacuum.

As shown in FIG. 1, a semiconductor manufacturing apparatus 1 includes a processing chamber 2 to which a wafer that is a semiconductor substrate such as a silicon substrate is transported and which subjects the wafer to surface treatment under vacuum. To the processing chamber 2, a vacuum pump 6 is coupled through an exhaust pipe 5. By this vacuum pump 6, the processing chamber 2 can be evacuated.

Between the processing chamber 2 and the vacuum pump 6, a pressure control valve 3 and a shutoff valve 4 are arranged. The pressure control valve 3 is a variable valve whose opening in the inside can be changed. By changing the opening of the pressure control valve 3, the exhausting rate of the processing chamber 2 by the vacuum pump 6 which corresponds to the pressure of the processing chamber 2 can be controlled.

The shutoff valve 4 is an opening and closing valve. Exhausting of the processing chamber 2 by the vacuum pump 6 is allowed by opening the shutoff valve 4, and exhausting of the processing chamber 2 by the vacuum pump 6 can be stopped by closing the shutoff valve 4.

To the downstream side namely the exhaust side of the vacuum pump 6, an exhaust pipe 7 is coupled. The exhaust gas exhausted from the vacuum pump 6 is discharged to an exclusion apparatus and an exhaust gas processing apparatus or an exhaust gas processing facility of the factory not illustrated through an exhaust system 8 from the vacuum pump.

To the vacuum pump 6, information transmission systems 11 and 12 are coupled. The electric current value and electric power value of a vacuum pump drive motor for the vacuum pump 6 are outputted to a pump state monitor 10 through the information transmission system 11. Also, analog data such as the temperature of the inside of the vacuum pump, the temperature of the vacuum pump drive motor, the intake pressure and exhaust pressure of the vacuum pump are outputted to the pump state monitor 10 through the information transmission system 12.

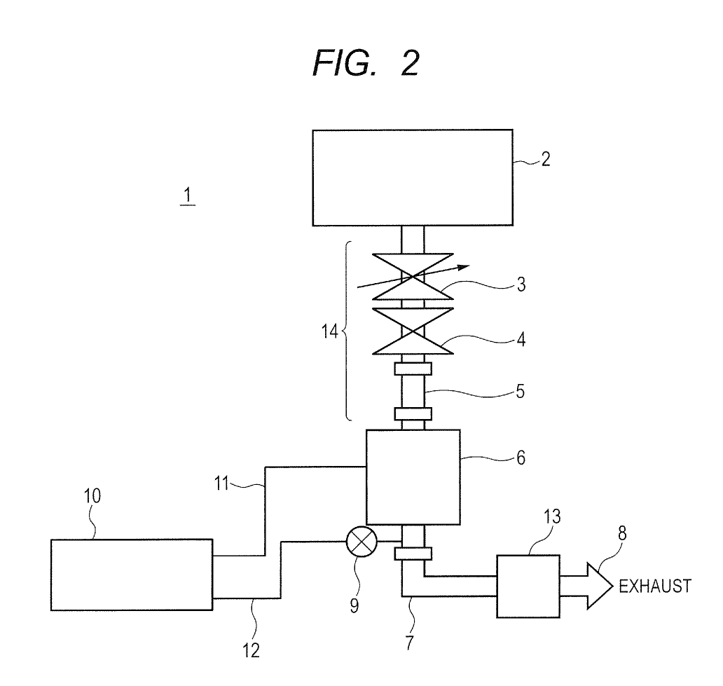

Next, the semiconductor manufacturing apparatus in the present embodiment will be explained using FIG. 2. Similarly to FIG. 1, FIG. 2 shows a general outline of a semiconductor manufacturing apparatus such as a CVD device and dry etching device which treats the wafer under vacuum.

The semiconductor manufacturing apparatus 1 shown in FIG. 2 is similar to the semiconductor manufacturing apparatus 1 of FIG. 1 in terms that the vacuum pump 6 is coupled with the processing chamber 2 through the exhaust pipe 5. Further, the point that the pressure control valve 3 and the shutoff valve 4 are arranged in an exhaust system 14 in the upstream of the vacuum pump 6 namely the exhaust system between the processing chamber 2 and the vacuum pump 6 is also similar to FIG. 1.

The semiconductor manufacturing apparatus 1 of FIG. 2 is different from the semiconductor manufacturing apparatus 1 of FIG. 1 in terms that an exhaust assisting device 13 is arranged on the downstream side of the vacuum pump 6, namely, in a part of the exhaust pipe 7 of the exhaust side of the vacuum pump 6. For this exhaust assisting device 13, a small pump, an exhaust injector, a vacuum generator, another vacuum pump different from the vacuum pump 6, and etc. are used for example.

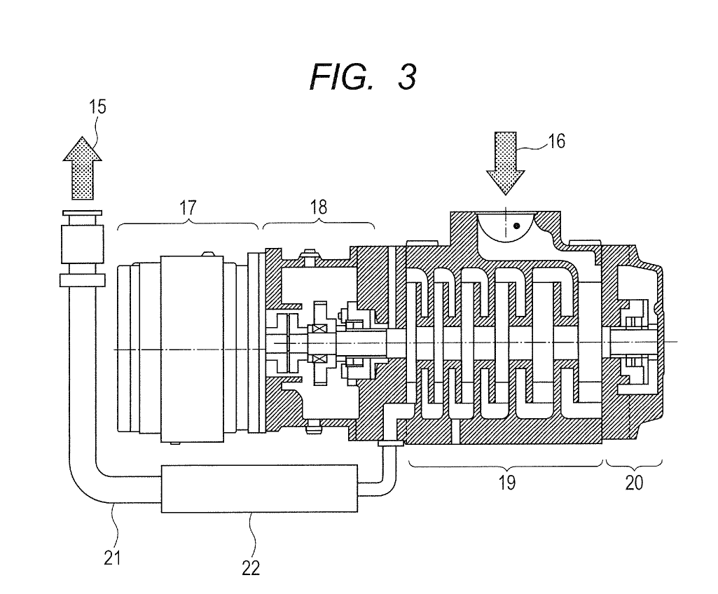

FIG. 3 shows a partial cross-sectional structure of the vacuum pump 6 in the semiconductor manufacturing apparatus 1 explained in FIG. 1 and FIG. 2. This vacuum pump 6 is a dry vacuum pump that does not use an oil component in the exhaust passage.

The structure of the vacuum pump 6 is formed of 4 portions of a pump motor unit 17, a bearing unit 18, a pump exhaust compressing unit 19, and a bearing unit 20 in rough classification. A pump intake 16 sucked from a suction port of the vacuum pump 6 is compressed by the pump exhaust compressing unit 19, and is discharged as pump exhaust 15 to the exhaust side of the vacuum pump 6 through an exhaust pipe 21. In the exhaust pipe 21 of the vacuum pump 6, a silencer 22 for muffling is arranged.

The electric power supplied to the vacuum pump 6 is used for driving the drive motor of the pump motor unit 17. In the pump motor unit 17, sensors for measuring the electric current value and the electric power value of the motor and the temperature of the motor are arranged. There is also a case that this sensor for measuring the temperature of the motor is arranged in another location other than the location of the motor and suitable to manage the temperature of the vacuum pump.

On the intake side of the vacuum pump 6, a pressure sensor for measuring the intake pressure is arranged. Also, on the exhaust side of the vacuum pump 6, a pressure sensor for measuring the exhaust pressure is arranged.

Here, for example, there are cases that the exhaust gas and the reaction product exhausted from the processing chamber 2 precipitate inside the pump exhaust compressing unit 19, and that biting occurs in the pump exhaust compressing unit 19 due to deterioration with time of the structure inside the pump exhaust compressing unit 19. In such cases, the load of the pump exhaust compressing unit 19 becomes large, and the motor power of the pump motor unit 17 also increases.

In the semiconductor manufacturing apparatus 1 in the present embodiment, as shown in FIG. 2, the exhaust assisting device 13 is arranged in the exhaust pipe 7 on the downstream side namely on the exhaust side of the vacuum pump 6, and the exhaust load of the vacuum pump 6 can be reduced. As a result, the electric current value of the vacuum pump drive motor, the electric power value of the vacuum pump drive motor, the internal temperature of the vacuum pump and the drive motor, the suction pressure of the vacuum pump, and the exhaust pressure of the vacuum pump can be reduced.

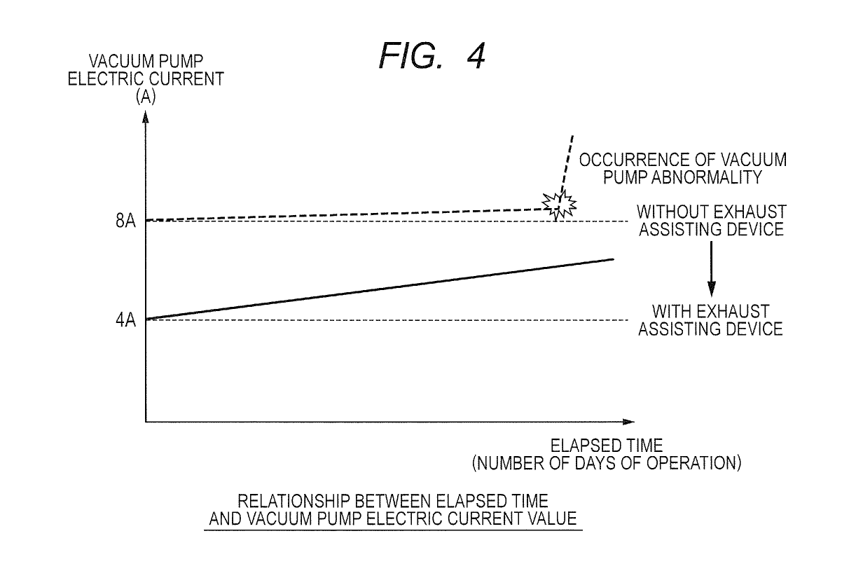

The failure prediction mechanism of a vacuum pump by the semiconductor manufacturing apparatus in the present embodiment will be explained using FIG. 4. The graph in the broken line in the drawing expresses the semiconductor manufacturing apparatus of a related art shown in FIG. 1, and the graph in the solid line expresses the semiconductor manufacturing apparatus of the present embodiment shown in FIG. 2.

When the exhaust assisting device 13 is not arranged on the exhaust side of the vacuum pump 6 as the semiconductor manufacturing apparatus 1 shown in FIG. 1, the electric current value of the pump motor unit 17 namely the vacuum pump electric current transitions at approximately 8 A. Also, because this vacuum pump electric current changes according to the kind and the displacement volume of the vacuum pump 6, the numerical value here is only for exemplification.

When the exhaust assisting device 13 is not arranged, because the vacuum pump 6 operates in a state close to the maximum of its exhausting capacity, even in a state the load starts to increase in the pump exhaust compressing unit 19, the fluctuation of the vacuum pump electric current is minute, and it is difficult to detect the fluctuation. As described above, the vacuum pump electric current value becomes such value that can detect occurrence of the abnormality immediately before biting occurs in the pump exhaust compressing unit 19 and the vacuum pump 6 unexpectedly stops or only after the vacuum pump 6 stops.

On the other hand, when the exhaust assisting device 13 is arranged on the exhaust side of the vacuum pump 6 as the semiconductor manufacturing apparatus 1 shown in FIG. 2, the electric current value of the pump motor unit 17 namely the vacuum pump electric current transitions at approximately 4 A. Also, because this vacuum pump electric current also changes according to the kind and the displacement volume of the vacuum pump 6, the numerical value here is only for exemplification.

As described above, when the exhaust assisting device 13 is arranged, because the load of the vacuum pump 6 is reduced, the electric current value of the vacuum pump drive motor, the electric power value of the vacuum pump drive motor, the internal temperature of the vacuum pump and the drive motor, the suction pressure of the vacuum pump, and the exhaust pressure of the vacuum pump reduce. As shown in FIG. 4, by reduction of the vacuum pump electric current from 8 A to 4 A, the fluctuation of the vacuum pump electric current becomes large, and detection of the fluctuation of the vacuum pump electric current becomes easy.

In other words, because the vacuum pump 6 was used in a high load state in the past, the fluctuation of the electric current value and the electric power value of the vacuum pump drive motor was hidden and could not be confirmed. However, by arranging the exhaust assisting device 13 on the exhaust side of the vacuum pump 6, the increment of the load of the vacuum pump 6 itself comes to be seen as the increase of the electric current value and the electric power value of the vacuum pump drive motor.

As a result, the minute change amount of the electric current value and the electric power value of the vacuum pump drive motor of the vacuum pump 6 can be confirmed.

The electric current value of the vacuum pump drive motor of the vacuum pump 6, the electric power value of the vacuum pump drive motor, the internal temperature of the vacuum pump and the drive motor, the suction pressure of the vacuum pump, and the exhaust pressure of the vacuum pump whose minute variation can be confirmed by arranging the exhaust assisting device 13 on the exhaust side of the vacuum pump 6 are transmitted to the pump state monitor 10 through the information transmission systems 11 and 12, and the drive state of the vacuum pump 6 is monitored.

The information of the drive state of the vacuum pump 6 transmitted to the pump state monitor 10 is outputted to the outside as an alarm signal when the value exceeds the set value of each data preset in the pump state monitor 10, or when the value deviates from the range of each data preset.

Other than the vacuum pump electric current shown in FIG. 4, the drive state of the vacuum pump 6 can be confirmed similarly also with respect to the electric power value of the vacuum pump drive motor, the internal temperature of the vacuum pump and the drive motor, the suction pressure of the vacuum pump, and the exhaust pressure of the vacuum pump, and similar results can be secured.

Thus, deterioration of the vacuum pump 6 and the failure such as biting in the pump exhaust compressing unit 19 can be predicted, and stable operation of the semiconductor manufacturing apparatus 1 becomes possible.

Also, by predicting the unexpected failure of the vacuum pump 6 beforehand, the wafer during processing in the processing chamber 2 can be prevented from becoming the scrap, and the process yield in the manufacturing step of the semiconductor device can be improved.

Further, because the exhaust assisting device 13 is arranged in a part of the exhaust pipe on the exhaust side of the vacuum pump 6, the load of the vacuum pump 6 can be reduced, and energy can be saved as the overall semiconductor manufacturing apparatus 1.

Also, in FIG. 1 and FIG. 2, the example of monitoring the drive state of one set of the vacuum pump 6 by one set of the pump state monitor 10 was shown, however, it is also possible to be configured that plural sets of the vacuum pumps 6 within the factory are monitored collectively by one set of the pump state monitor 10.

Furthermore, it is also possible to monitor the drive state of the vacuum pump 6 by incorporating the pump state monitoring function into the monitoring system of the overall semiconductor manufacturing apparatus for example instead of monitoring by the pump state monitor 10.

Also, by arranging the exhaust assisting device 13 on the downstream side of the vacuum pump 6, presence/absence of the vacuum leakage of the exhaust system 14 of the upstream of the vacuum pump can be detected.

Intrinsically, the electric current value and electric power value should change by reduction of the load of the vacuum pump 6 by the exhaust assisting device 13, however, when there is no change, it is highly probable that the load increases on the upstream side of the vacuum pump 6. In this case, possibility of the vacuum leakage can be pointed out.

In other words, when the electric current value and electric power value of the vacuum pump drive motor remain at a high value in spite that the exhaust of the vacuum pump 6 is reduced by the exhaust assisting device 13, it is highly probable that the load increases on the upstream side of the vacuum pump 6. Therefore, it results that a load greater than the load of the vacuum pump 6 which has been reduced by the exhaust assisting device 13 is generated on the upstream side of the vacuum pump 6.

In this case, vacuum leakage is highly probable. When it is during monitoring the state, the electric current value and electric power value of the vacuum pump drive motor continuously remain at a high value, and the error has not occurred in the vacuum pump 6 itself, it is highly probable that the leakage has occurred on the upstream side of the vacuum pump 6. In other words, presence/absence of the vacuum leakage of the exhaust system on the upstream side of the vacuum pump 6 of the semiconductor manufacturing apparatus 1 can be diagnosed.

According to the present embodiment, operation of the semiconductor manufacturing apparatus 1 can be stabilized utilizing the effects as described above.

### Second Embodiment

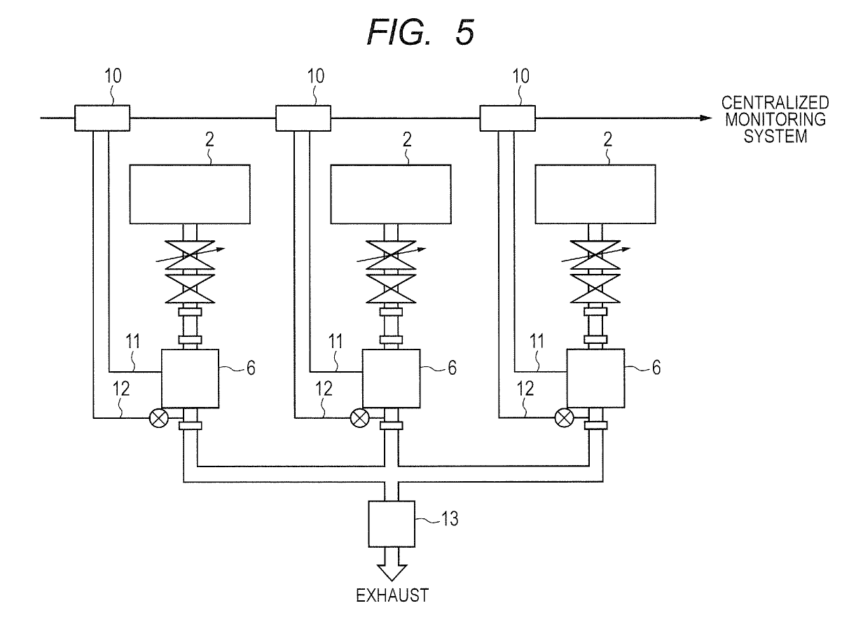

The semiconductor manufacturing apparatus in the second embodiment will be explained using FIG. 5. FIG. 5 shows an example in which the individual vacuum pump 6 is coupled with each processing chamber 2 of the plural sets of the semiconductor manufacturing apparatus 1 and the exhaust pipes of the exhaust side of the respective vacuum pumps 6 are integrated into 1 system.

As shown in FIG. 5, the exhaust assisting device 13 is arranged in the exhaust system after integrating the exhaust systems of the respective vacuum pumps 6 of the plural sets of the semiconductor manufacturing apparatus 1 into 1 system.

When another vacuum pump having the exhausting performance of a same degree of that of the vacuum pump 6 for example is employed for the exhaust assisting device 13 as explained in the first embodiment, the exhausting performance of the exhaust assisting device 13 becomes excessive, and there is a risk that the energy saving effect as the overall semiconductor manufacturing apparatus cannot be secured.

Therefore, according to the semiconductor manufacturing apparatus in the second embodiment, the exhaust pipes on the exhaust side of the vacuum pumps 6 respectively coupled with the plural sets of the semiconductor manufacturing apparatus 1 are integrated into 1 system, 1 set of the exhaust assisting device 13 is thereafter arranged in the integrated exhaust system which means that 1 set of the exhaust assisting device 13 is shared by the plural sets of the vacuum pump 6, and thereby the energy saving effect as the overall semiconductor manufacturing apparatus of the plural sets can be maintained while reducing the load of each vacuum pump 6.

Also, according to the second embodiment, the drive state of each vacuum pump 6 is transmitted to the pump state monitor 10 individually arranged for each vacuum pump 6 through the information transmission systems 11 and 12, and the drive state of the plural sets of the vacuum pump 6 is transmitted to the centralized monitoring system of the factory, and thereby the drive state of each vacuum pump 6 is monitored collectively.

Thus, the individually coupled vacuum pumps 6 of the plural sets of the semiconductor manufacturing apparatus 1 can be monitored collectively, and the plural sets of the semiconductor manufacturing apparatus can be operated stably.

According to the semiconductor manufacturing apparatus of the second embodiment, similarly to the first embodiment, deterioration of the vacuum pump 6 and the failure such as biting in the pump exhaust compressing unit 19 can be predicted, and the plural sets of the semiconductor manufacturing apparatus can be operated stably.

Also, by predicting the unexpected failure of the vacuum pump 6 beforehand, the wafer during processing in the processing chamber 2 can be prevented from becoming the scrap, and the process yield in the manufacturing step of the semiconductor device can be improved.

Further, after the exhaust pipes on the exhaust side of the plural sets of the vacuum pump 6 are integrated into 1 system, the exhaust assisting device 13 is arranged in a part of the exhaust pipe integrated, therefore the load of the plural sets of the vacuum pump 6 can be reduced simultaneously, and energy can be saved as the overall semiconductor manufacturing apparatus group.

### Third Embodiment

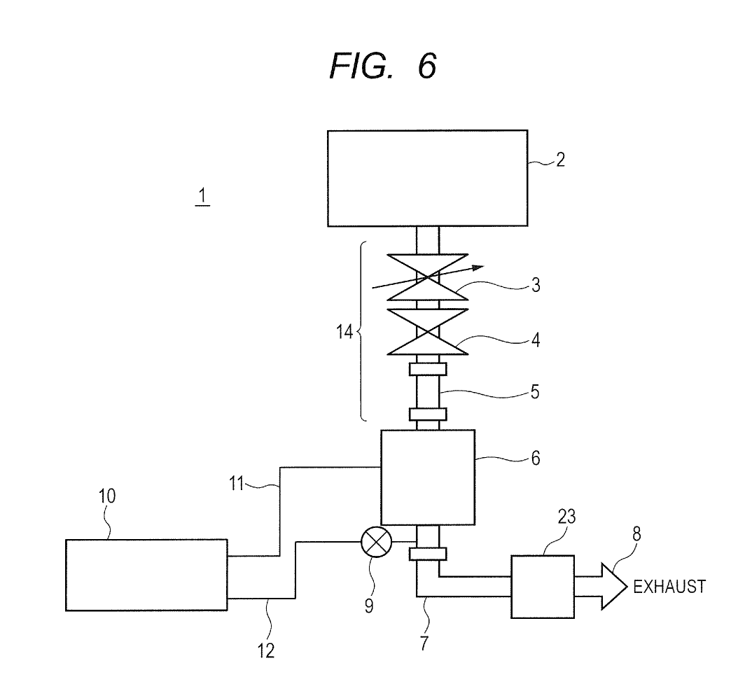

The semiconductor manufacturing apparatus in the third embodiment will be explained using FIG. 6. Similarly to FIG. 2, FIG. 6 shows a general outline of a semiconductor manufacturing apparatus such as a CVD device and a dry etching device which treats the wafer under vacuum.

The semiconductor manufacturing apparatus 1 shown in FIG. 6 is similar to the semiconductor manufacturing apparatus 1 of FIG. 2 in terms that the vacuum pump 6 is coupled with the processing chamber 2 through the exhaust pipe 5. Further, the point that the pressure control valve 3 and the shutoff valve 4 are arranged in the exhaust system 14 in the upstream of the vacuum pump, namely, the exhaust system between the processing chamber 2 and the vacuum pump 6 is also similar to FIG. 2.

The semiconductor manufacturing apparatus 1 of FIG. 6 is different from the semiconductor manufacturing apparatus 1 of FIG. 2 in terms that an exhaust loading device 23 is arranged in a part of the exhaust pipe 7 on the downstream side, namely, the exhaust side of the vacuum pump 6. For this exhaust loading device 23, a nitrogen gas introducing device that introduces nitrogen gas to the exhaust side of the vacuum pump 6 and the like is used for example.

The drive state of the vacuum pump 6 is monitored by the pump state monitor 10 in a state the exhaust loading device 23 is arranged in a part of the exhaust pipe 7 on the downstream side of the vacuum pump 6 as shown in FIG. 6 and the vacuum pump 6 is loaded excessively.

With respect to the drive state of the vacuum pump 6, similarly to the first embodiment or the second embodiment, the electric current value of the vacuum pump drive motor, the electric power value of the vacuum pump drive motor, the internal temperature of the vacuum pump and the drive motor, the suction pressure of the vacuum pump, and the exhaust pressure of the vacuum pump are monitored.

Thus, the capacity of the vacuum pump 6 at the time of excessive loading can be measured by temporarily reducing the exhausting capacity of the vacuum pump 6, and the state of the vacuum pump 6 can be diagnosed.

### Fourth Embodiment

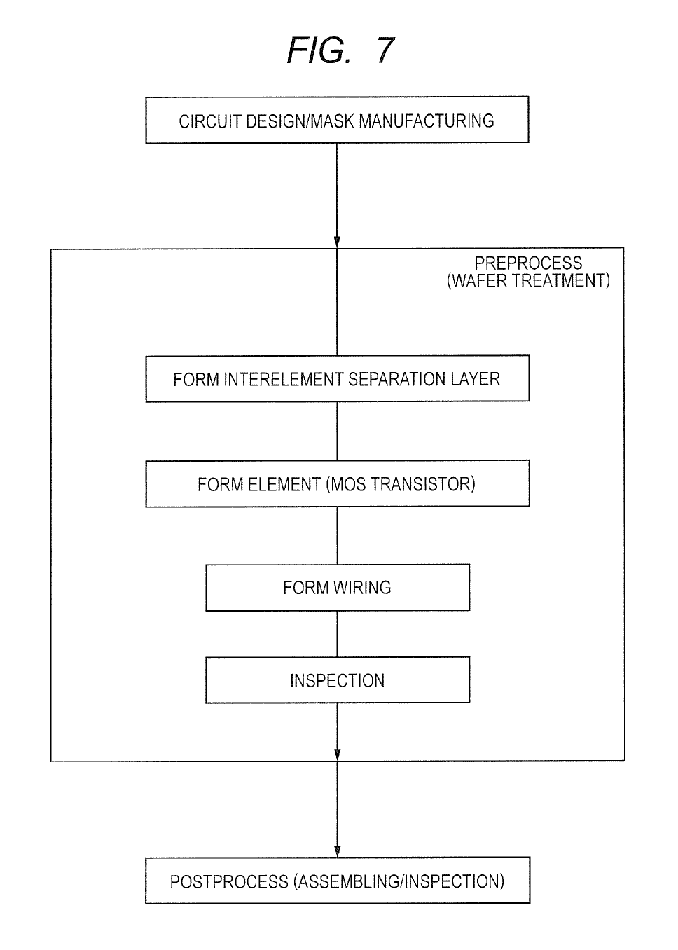

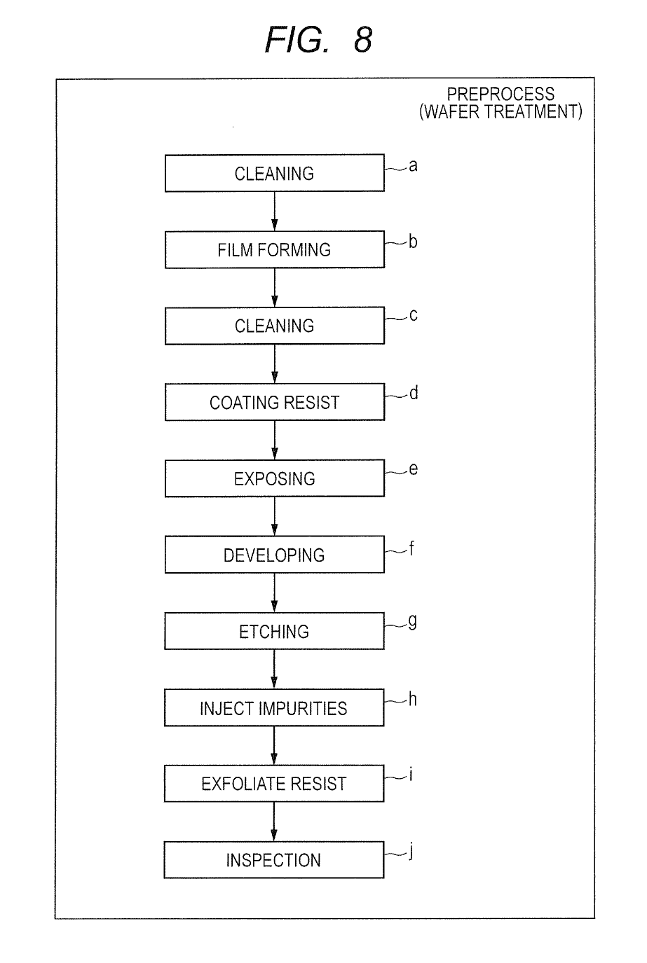

The method for manufacturing the semiconductor device such as a microcomputer and a memory by the semiconductor manufacturing apparatus explained in the first embodiment or the second embodiment will be explained using FIG. 7 and FIG. 8. FIG. 7 is a flowchart showing an outline of the manufacturing step of a semiconductor device. Also, FIG. 8 is a flowchart showing an outline of a preprocess of the manufacturing step of a semiconductor device.

The manufacturing step of the semiconductor device such as a microcomputer and a memory can be divided into 3 steps in rough classification as shown in FIG. 7.

First, a semiconductor circuit is designed, and a mask is manufactured based on the circuit design.

Next, in a wafer processing step called a preproces, an integrated circuit is formed by repeating to subject the surface of the semiconductor substrate (wafer) such as silicon to various surface treatments plural times. This preprocess includes a step for forming an element separation layer, a step for forming an element such as a MOS transistor, a wiring forming step for forming an interlayer insulation film and wiring over each element, a step for inspecting the wafer completed, and so on in rough classification as shown in FIG. 7.

Also, in the postprocess, the wafer whose surface is formed with the integrated circuit is separated individually, is assembled into a semiconductor device, and is inspected.

In the preprocess that is the wafer processing step, plural surface treatments from step a to step j shown in FIG. 8 are repeated plural times.

First, the surface of the wafer that is the semiconductor substrate where the element such as a MOS transistor is formed is cleaned, and the foreign matter and impurities adhered to the wafer surface are removed (step a).

Next, a thin film is formed over the wafer surface using a CVD device and the like. This thin film is a film for forming an interlayer insulation film such as a silicon oxide film and wiring such as an aluminum film and so on (step b).

After the thin film is formed over the wafer surface, the foreign matter and impurities adhered to the surface are removed by cleaning again (step c).

Over the wafer whose surface is formed with the film for forming the interlayer insulation film and the wiring, a resist material formed of a sensitized material and the like is coated (step d).

Using the mask in which a desired circuit pattern has been formed, the circuit pattern is transferred to the resist by an exposure device (step e).

In a developing process, the resist of an unnecessary portion is removed, and the desired circuit pattern is formed in the resist over the wafer (step f).

The unnecessary portion of the thin film formed over the wafer is removed by etching by a dry etching device using the resist formed with the desired circuit pattern as the etching mask, and the desired circuit pattern is formed in the thin film (step g).

Thereafter, according to the necessity, the impurities are injected to the wafer surface by an ion implantation apparatus (step h).

The resist formed over the wafer is exfoliated (removed) by asking treatment and cleaning (step i).

Lastly, presence/absence of the foreign matter over the wafer and the event the desired pattern has been precisely formed in the thin film are inspected by a foreign matter inspection apparatus and an outer appearance inspection apparatus (step j).

Also, between step a to step j described above, treatments of cleaning, drying and the like of the wafer are executed according to the necessity.

According to the method for manufacturing the semiconductor device in the present embodiment, in the film forming step of step b or the etching step of step g described above, the treatment is executed using such semiconductor manufacturing apparatus as explained in the first embodiment or the second embodiment.

More specifically, in the film forming step of step b, the exhaust assisting device is arranged in a part of the exhaust pipe on the exhaust side of the vacuum pump coupled with the processing chamber of the film forming device such as a CVD device, and the film forming treatment is executed monitoring the drive state of the vacuum pump.

Also, in the etching step of step g, the exhaust assisting device is arranged in a part of the exhaust pipe on the exhaust side of the vacuum pump coupled with the processing chamber of the etching device such as a dry etching device, and the etching treatment is executed monitoring the drive state of the vacuum pump.

By monitoring the drive state of the vacuum pump more precisely than the past in the film forming step of step b or the etching step of step g, when the abnormality of the drive state of the vacuum pump is detected, replacement or maintenance of the pump becomes possible beforehand. By preventing the unexpected failure of the vacuum pump, during forming the film and during etching, the scrap of the wafer generated by the failure of the vacuum pump can be reduced.

Also, for example, in the film forming step of step b, the interlayer insulation film such as the silicon oxide film is formed so as to cover the MOS transistor and the like. Further, in the etching step of step g, a contact hole that reaches the source region or the drain region of the MOS transistor is formed in the interlayer insulation film. At this time, there is a case etching stops in the middle due to stop of the vacuum pump in the middle of the etching step of step g.

In the case of such trouble, even when etching treatment for forming the contact hole which has been suspended once is executed again, it is difficult to form the desired contact hole. As a result, it is highly probable that the wafer whose treatment has been stopped in the middle of etching becomes the scrap, or that the desired contact hole cannot be secured to cause the product defect even when the etching treatment is executed again.

As described above, according to the method for manufacturing the semiconductor device of the present embodiment, by using the dry etching device provided with the exhaust assisting device in the etching step of step g, the trouble during etching in forming the contact hole can be prevented beforehand, and the scrap of the wafer and the product defect can be reduced.

In step b (film forming step) or step g (etching step), measurement of the drive state of the vacuum pump of the CVD device or the dry etching device is not limited to the time during the film forming treatment or during the etching treatment. For example, the drive state of the vacuum pump may be measured in a state the exhaust assisting device is driven when the wafer is transported into the processing chamber and the processing chamber is evacuated by the vacuum pump. When the abnormality of the vacuum pump can be detected before the film forming treatment or the etching treatment starts, the scrap of the wafer and the product defect can be prevented more surely. Therefore, the productivity in producing the semiconductor device can be improved.

Although the invention achieved by the present inventors has been explained above specifically based on the embodiments, it is needless to mention that the present invention is not limited to the embodiments and various alterations are possible within a scope not deviating from the purposes thereof.

What is claimed is:

1. A semiconductor manufacturing apparatus comprising:
a processing chamber where a wafer is treated;
a vacuum pump that is coupled with the processing chamber and evacuates the processing chamber;
a monitor that measures the drive state of the vacuum pump; and
an exhaust assisting device that is arranged on the exhaust side of the vacuum pump,
wherein the monitor measures the drive state of the vacuum pump in a state the vacuum pump and the exhaust assisting device are driven.

2. The semiconductor manufacturing apparatus according to claim 1,
wherein the monitor measures at least one parameter out of the electric current value, electric power value and motor temperature of a vacuum pump drive motor, and the suction pressure and exhaust pressure of the vacuum pump.

3. The semiconductor manufacturing apparatus according to claim 1,
wherein the exhaust assisting device is any one of a small pump, an exhaust injector, a vacuum generator, and another vacuum pump different from the vacuum pump.

4. The semiconductor manufacturing apparatus according to claim 1,
wherein the monitor outputs an alarm signal to the outside when the drive state of the vacuum pump measured exceeds a preset value.

5. A diagnostic system for a semiconductor manufacturing apparatus, comprising:
a processing chamber where a wafer is treated;
a vacuum pump that is coupled with the processing chamber and evacuates the processing chamber;
a monitor that measures the drive state of the vacuum pump; and
an exhaust loading device that is arranged on the exhaust side of the vacuum pump,
wherein the drive state of the vacuum pump is measured in a state the vacuum pump and the exhaust loading device are driven.

6. The diagnostic system for a semiconductor manufacturing apparatus according to claim 5,
wherein the monitor measures at least one parameter out of the electric current value electric power value and motor temperature of a vacuum pump drive motor, and the suction pressure and the exhaust pressure of the vacuum pump.

7. The diagnostic system for a semiconductor manufacturing apparatus according to claim 5,
wherein the exhaust loading device is a nitrogen gas introducing device that introduces nitrogen gas to the exhaust side of the vacuum pump.

8. The diagnostic system for a semiconductor manufacturing apparatus according to claim 5,
wherein the monitor outputs an alarm signal to the outside when the drive state of the vacuum pump measured exceeds a preset value.

9. A method for manufacturing a semiconductor device executed using a semiconductor manufacturing apparatus comprising:
a processing chamber where a wafer is treated;
a vacuum pump that is coupled with the processing chamber and evacuates the processing chamber;
a monitor that measures the drive state of the vacuum pump; and
an exhaust assisting device that is arranged on the exhaust side of the vacuum pump,
the method for manufacturing a semiconductor device comprising the steps of:
(a) transporting the wafer into the processing chamber;
(b) evacuating the processing chamber by a vacuum pump coupled with the processing chamber;
(c) subjecting the wafer to a treatment within the processing chamber while evacuating the processing chamber by the vacuum pump; and
(d) measuring the drive state of the vacuum pump in a state the exhaust assisting device is driven in at least either one of the step (b) and the step (c).

10. The method for manufacturing a semiconductor device according to claim 9,
wherein at least one parameter out of the electric current value, electric power value and motor temperature of a vacuum pump drive motor, and the suction pressure and exhaust pressure of the vacuum pump are measured in the step (d).

11. The method for manufacturing a semiconductor device according to claim 9,
wherein the exhaust assisting device is any one of a small pump, an exhaust injector, a vacuum generator, and another vacuum pump different from the vacuum pump.

12. The method for manufacturing a semiconductor device according to claim 9,
wherein an alarm signal is outputted to the outside when the drive state of the vacuum pump measured exceeds a preset value.

13. The method for manufacturing a semiconductor device according to claim 9, wherein the step (c) comprises the steps of:
(c1) forming a MOS transistor over a semiconductor substrate;
(c2) forming an interlayer insulation film over the MOS transistor; and
(c3) forming a contact hole that reaches a source region or a drain region of the MOS transistor in the interlayer insulation film.

14. The method for manufacturing a semiconductor device according to claim 13,
wherein the semiconductor manufacturing apparatus is a CVD device, and
wherein the step (d) is executed during the step (c2).

15. The method for manufacturing a semiconductor device according to claim 13,
wherein the semiconductor manufacturing apparatus is a dry etching device, and
wherein the step (d) is executed during the step (c3).
